(19) United States
(12) Patent Application Publication
(10) Pub. No.: US 2017/0133460 A1
(43) Pub. Date: May 11, 2017

(54) SEMICONDUCTOR STRUCTURE AND MANUFACTURING METHOD THEREOF

(71) Applicant: UNITED MICROELECTRONICS CORP., Hsin-Chu City (TW)

(72) Inventors: Tien-I Wu, Taoyuan City (TW); I-cheng Hu, Kaohsiung City (TW); Yu-Shu Lin, Pingtung County (TW); Chun-Jen Chen, Tainan City (TW); Tsung-Mu Yang, Tainan City (TW); Kun-Hsin Chen, Pingtung County (TW); Neng-Hui Yang, Hsinchu City (TW); Shu-Yen Chan, Changhua County (TW)

(21) Appl. No.: 14/936,651

(22) Filed: Nov. 9, 2015

(51) Int. Cl. H01L 29/06; H01L 21/3065; H01L 29/16; H01L 21/283; H01L 29/423; H01L 21/306; H01L 21/225

(52) U.S. Cl. CPC H01L 29/0649; H01L 21/30604; H01L 21/3065; H01L 21/2253; H01L 21/283; H01L 29/42356; H01L 29/16

(57) ABSTRACT

The present invention provides a method for forming a semiconductor structure, including: first, a substrate is provided. Next, at least two gate structures are formed on the substrate, each gate structure including two spacers disposed on two sides of the gate structure. Afterwards, a dry etching process is performed to remove parts of the substrate, so as to form a recess in the substrate, and a wet etching process is performed, to etch partial sidewalls of the recess, so as to form at least two tips on two sides of the recess respectively. In addition, parts of the spacer are also removed through the wet etching process, and each spacer includes a rounding corner disposed on a bottom surface of the spacer.

### BACKGROUND OF THE INVENTION

1. Field of the Invention

The invention relates to a semiconductor structure and manufacturing method thereof, and more particularly, to a semiconductor structure with a specific shaped spacer and manufacturing method thereof.

2. Description of the Prior Art

With semiconductor processes entering the era of the deep submicron meter below 65 nanometer (nm), it has been more and more important to increase the metal-oxide semiconductor (MOS) drive current. To improve device performance, a strained-silicon technique such as a selective epitaxial growth (SEG) method is developed to form epitaxial layers serving as the source/drain of the MOS. Because a lattice constant of the epitaxial layer is different from that of silicon, such characteristic is employed to cause alteration to the band structure of the silicon in the channel region. Accordingly, carrier mobility of the channel region is enhanced and thus device performance is improved.

### SUMMARY OF THE INVENTION

The present invention provides a method for forming a semiconductor structure, comprising: first, a substrate is provided, next, at least two gate structures are formed on the substrate, each gate structure including two spacers disposed on two sides of the gate structure, afterwards, a dry etching process is performed, to remove parts the substrate, so as to form a recess in the substrate, and a wet etching process is performed, to etch partial sidewalls of the recess, so as to form at least two tips on two sides of the recess respectively, in addition, parts of the spacer are also removed through the wet etching process, and each spacer comprises a rounding corner disposed on a bottom surface of the spacer.

The present invention also provides a semiconductor structure, comprising: a substrate, at least two gate structures disposed on the substrate, at least two spacers disposed on two sides of each gate structure, wherein each spacer comprises a rounding corner on a bottom surface of the spacer, and a recess disposed in the substrate between two gate structures, wherein the recess has a polygonal shaped cross section profile, and has at least two tips on two sides of the recess.

One key feature of the present invention is that in order to avoid the defects occurring between the silicon surface and the silicon nitride surface, during the wet etching process, the spacer will also be partially removed, so as to form the spacers with the rounding corners, and the sharp corner of the spacer will not be formed. Therefore, the epitaxial layer can be formed on a smooth and concave surface conformally but not touching a sharp corner, thereby improving the quality of the epitaxial layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a schematic drawing illustrating a semiconductor structure applied with the SEG method.

FIGS. 2-6 are drawings illustrating a manufacturing method for a semiconductor structure provided by a preferred embodiment of the present invention.

FIG. 7 shows another case of the semiconductor structure without forming the rounding corner.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

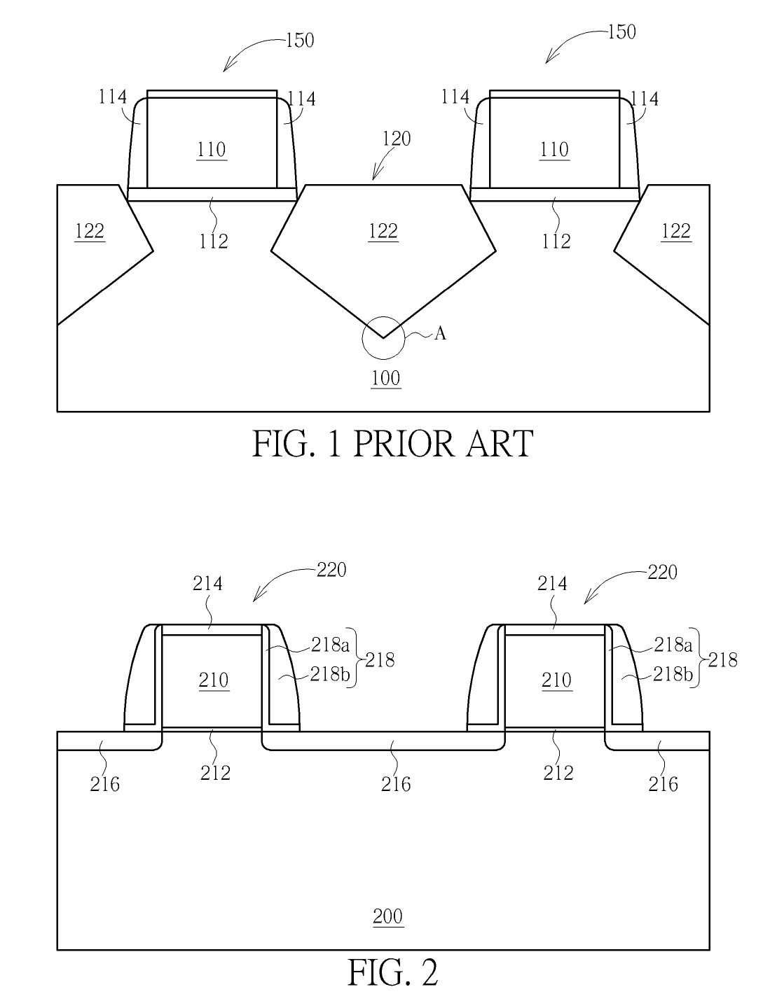

Please refer to FIG. 1, which is a schematic drawing illustrating a semiconductor structure applied with the SEG method. As shown in FIG. 1, a semiconductor device 150 is positioned on a substrate 100. The semiconductor structure 150 includes a gate conductive layer 110 and a gate dielectric layer 112. A spacer 114 is formed on the sidewalls of the gate conductive layer 110 and the gate dielectric layer 112, and recesses 120 are respectively formed in the substrate 100 at two sides of the spacer 114. The recess 120 includes an epitaxial layer 122 formed therein. Furthermore, it is well-known that the epitaxial layer 122 is formed along the surface of the recess 120 during the SEG method. Therefore shapes and crystalline orientation of each surface of the recess 120 also render impact to the epitaxial layer 122. For example, the recess 120 of the conventional semiconductor device 150 typically includes a V shape, therefore the epitaxial layer 122 formed along the surfaces of the recesses 120 obtains a V-shaped tip (as emphasized by circle A). Moreover, it is found that device leakage always occurs at the tip.

Please refer to FIGS. 2-6, which are drawings illustrating a manufacturing method for a semiconductor structure provided by a preferred embodiment of the present invention. As shown in FIG. 2, the preferred embodiment first provides a substrate 200. The substrate 200 includes a gate structure 220 formed thereon, and the gate structure 220 includes a gate dielectric layer 212, a gate conductive layer 210, and a cap layer 214 sequentially and upwardly stacked on the substrate 200. It is well-known to those skilled in the art that the cap layer 214 is formed to cover the gate conductive layer 210 to protect the gate conductive layer 210 from damage that may be caused in any process such as photolithograph process, ion implantation, etching process, or any needed cleaning process in the semiconductor fabricating process. LDDs 216 are formed in the substrate 200 at two sides of the gate conductive layer 210 and the gate dielectric layer 212 of the gate structure 220. A spacer 218 is formed on sidewalls of the gate conductive layer 210 and the gate dielectric layer 212. As shown in FIG. 2, the spacer 218 preferably is a multi-layered structure including an L-shaped seal layer 218a made of silicon oxide and an insulating layer 218b made of silicon nitride covering the seal layer 218a. The spacer 218 formed on the sidewalls of the gate conductive layer 210 and the gate dielectric layer 212 after forming the LDDs 216 is used to protect the sidewalls of the gate conductive layer 210 and the gate dielectric layer 212.

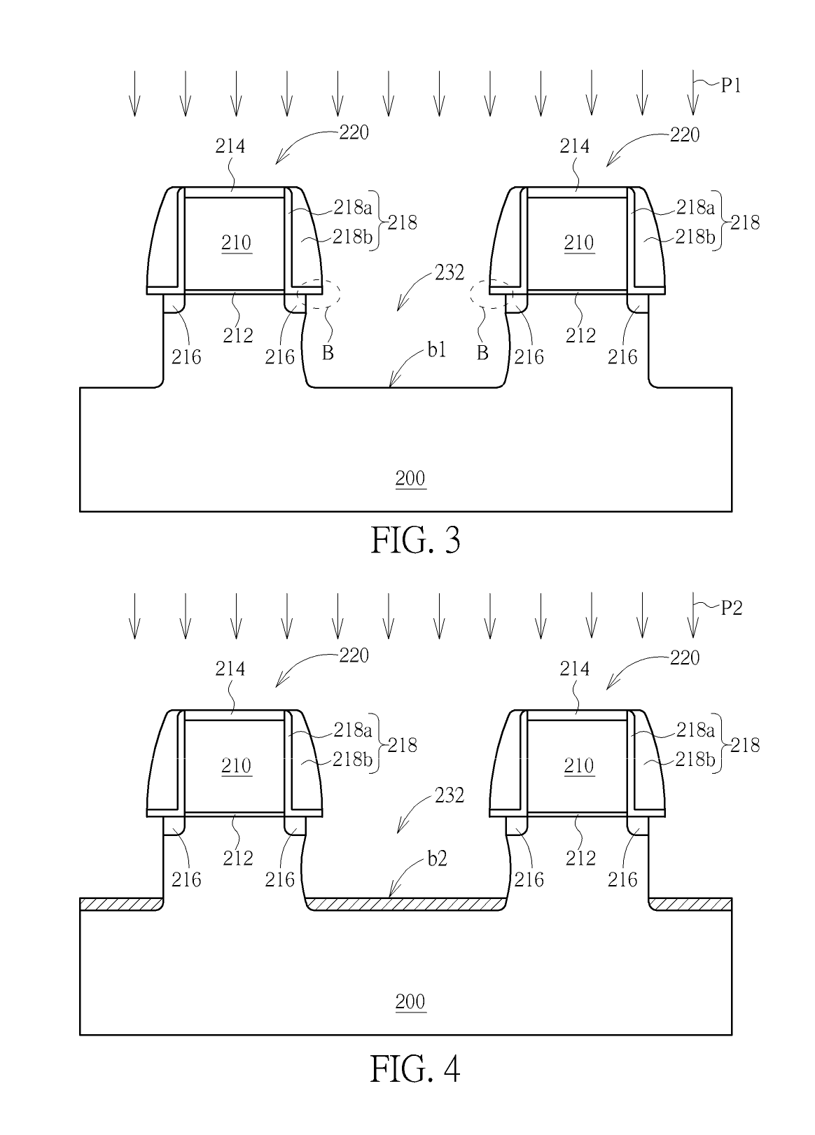

Please refer to FIG. 3. Next, a dry etching process P1 is performed to etch the substrate 200 disposed on two sides of the gate structure 220 and the spacer 218. Preferably, the dry etching process P1 is a gas etching process using fluorine (F) or chlorine (Cl) and mixed with helium as the carrier gases. Besides, the etching gas does not contain nitrogen trifluoride (NF₃). After the dry etching process P1 is performed, a recess 232 is formed in the substrate 200, and the recess 232 is at least disposed between two gate structures 220. In addition, the recess 232 may a Ω shaped profile and a flat bottom surface b1.

In this embodiment, the etching process P1 is an isotropic etching process, and an etching gas to silicon nitride and silicon may be used to form the recess 232 by adjusting the ratio between the fluorine, chlorine (Cl) and helium in the etching gas. In this step, both the substrate 200 and the spacer 218 will be etched during the etching process P1, but the etching rate for etching the silicon substrate is faster than the etching rate for etching the spacer, so after the etching process P1 is performed, parts of a bottom surface of each spacer 218 are exposed (as emphasized by circle B shown in FIG. 3), and a “pullback” phenomenon will occur, which means the inner surface of the recess 232 is over-etched and expended outwardly. Besides, since the etching process P1 is an isotropic etching process, after the etching process P1 is performed, parts of the recess 232 are disposed right under the spacer 218. It is noteworthy that in this embodiment, the etching gas of the etching process P1 does not include NF₃. According to applicant's experiment, if the etching gas contains NF₃, the etching selectivity of the silicon to the silicon nitride will be decreased, and therefore, parts of the bottom surface of the spacer 218 cannot be exposed during the etching process P1.

As shown in FIG. 4. Afterwards, a treatment process, such as an ion implantation P2 can be selectively performed, to implant specific ions into the bottom surface b1 of the recess 232, and in this embodiment, the ions used in the ion implantation process P2 include boron ions, phosphate ions, arsenic ions, germanium ions, argon ions or a combination thereof. After the ion implantation process P2 is performed, the anti-etching ability of the bottom surface b1 of the recess 232 is improved, and an anti-etching bottom surface b2 will be formed in the recess 232. In other words, in the following etching processes, the bottom surface b2 is more difficult to be etched than the sidewall of the recess 232 is. Besides, in another case, the ion implantation P2 can be omitted, it should also be within the scope of the present invention.

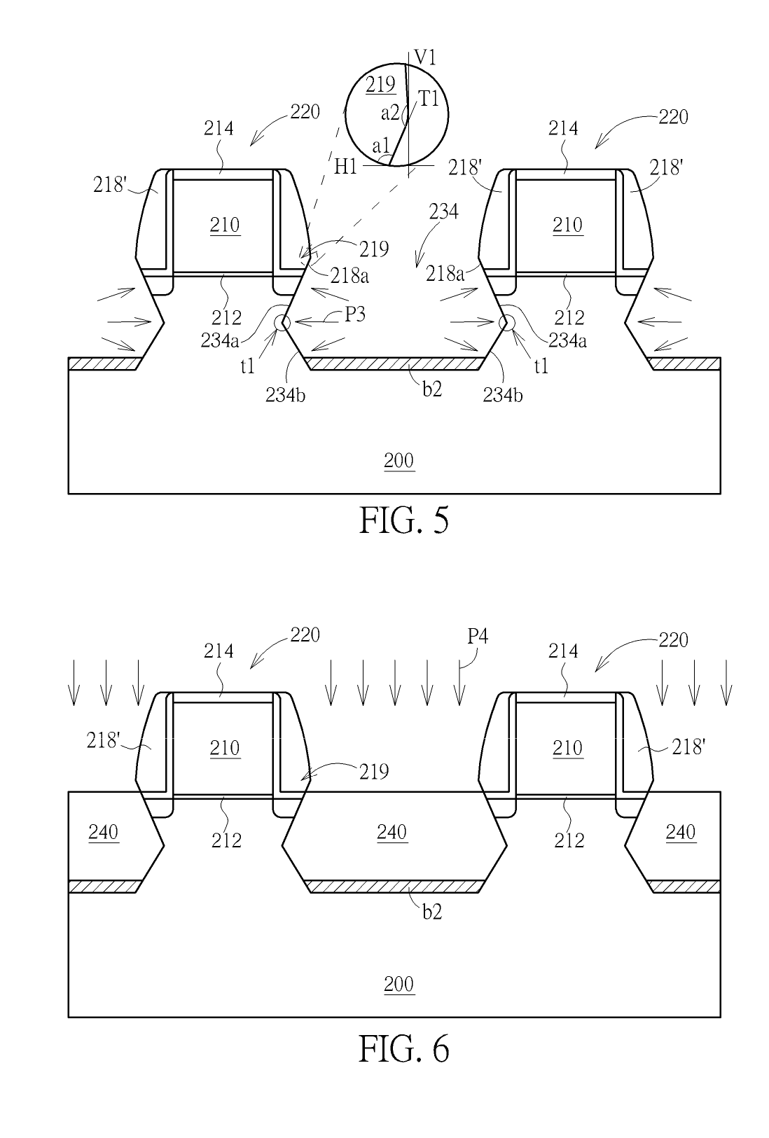

Please refer to FIG. 5. Next, a wet etching process P3 is performed to etch the recess 232 with a tetra methyl ammonium hydroxide ((CH₃)₄NOH, TMAH) solution or a dilute hydrofluoric acid (DHF). In other words, the wet etching process P3 is a TMAH/DHF wet etching process. In the preferred embodiment, a concentration of TMAH in the TMAH solution is lower than 5%, and a concentration of water (H₂O) is higher than 95%. The wet etching process P3 is performed at a temperature of about 70° C., but not limited to this. In one case, since the bottom surface b2 with higher anti-etching ability is already formed in the recess 232 during the ion implantation process P2, during the wet etching process P3, the etching rate for etching the sidewall of the recess 232 is faster than the etching rate for etching the bottom surface b2. And after the wet etching process P3, the shape (profile) of the recess 232 is changed, and becomes a recess 234 with polygonal cross-section profile. Preferably, the recess 234 has a diamond shaped profile or a hexagonal shaped profile, and having two first sidewalls 234a and two second sidewalls 234b, a tip t1 is between one first sidewall 234a and one second sidewall 234b. In other words, as shown in FIG. 5, the recess 234 has two tips t1, disposed on two sidewalls of the recess 234 respectively, and the two tips t1 are disposed on a same level.

It is noteworthy that during the wet etching process P3, the etching rate for etching the spacer 218 is faster than the etching rate for etching the silicon substrate 200. Therefore, parts of the spacer 218 are also removed, so as to form a plurality of spacers 218′, and each spacer 218′ has a rounding corner 219 disposed on a bottom surface of each spacer 218′. Besides, between a sidewall 234a of the recess 234 and a sidewall 218a of the spacer 218′, the interface is a smooth concave surface. In the present invention, an angle a1 between a tangent line T1 of the rounding corner 219 and a horizontal line H1 is between 90 and 180 degrees, and an angle a2 between the tangent line T1 of the rounding corner 219 and a vertical line V1 is between 90 and 180 degrees too.

Please refer to FIG. 6. Next, a SEG method P4 is performed to form an epitaxial layer 240 in the recess 234, and the epitaxial layer 240 fills up the recess 234. It is well-known to those skilled in the art that in the SEG method P4, the epitaxial layer 240 is to grow along each surface of the recess 234. Therefore the epitaxial layer 240 having a diamond shape shown in FIG. 6 is formed. The epitaxial layers 240 can be used as a source/drain region of a transistor. It is noteworthy that since the recess 234 includes the flat bottom surface b2, the epitaxial layer 240 obtains a flat bottom accordingly. Furthermore, in the present invention, the epitaxial layer 240 can include a silicon germanium (SiG) epitaxial layer or a boron-doped silicon germanium (SiGB) epitaxial layer or a silicon phosphide (SiP) epitaxial layer or a phosphorous-doped silicon carbide (SiCP) epitaxial layer required by p-type or n-type semiconductor structure. Additionally, the cap layer 214 is selectively removed and followed by performing a silicide process to form silicide (not shown) at least on the surface of the epitaxial layers 240. Besides, the embodiment mentioned above takes a planar transistor as an example, but the present invention can also be applied to non-planar transistors, such as finFET, and it should also be within the scope of the present invention.

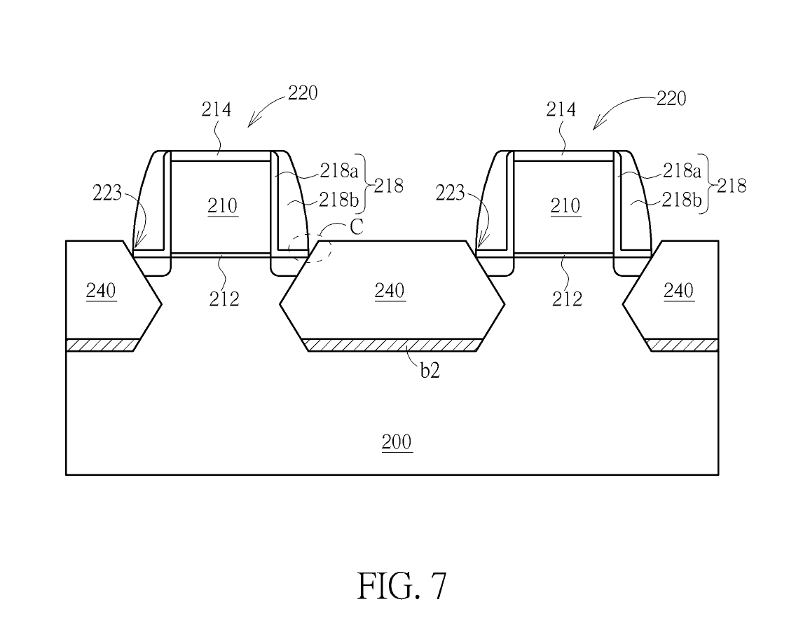

The epitaxial layer 240 is easy to grow along the silicon surface (such as the inner surface of the recess 234), but it cannot be formed on the surface made of others materials (such as the silicon oxide or the silicon nitride) easily. In other words, in conventional process, the epitaxial layer cannot be formed on the surface of the spacer easily. Therefore, please refer to FIG. 7, which shows another case of the semiconductor structure without forming the rounding corner mentioned in FIG. 5. As shown in FIG. 7, if the rounding corners are not formed, each spacer will have a “sharp corner 223” disposed below, and while the SEG method P4 is performed, as emphasized by circle C shown in FIG. 7, while the epitaxial layer 240 grows along the inner surface of the recess and contacts the sharp corner 223, the epitaxial layer 240 is easily peeled off on the interface between the silicon surface (the inner surface of the recess 234) and the surface of the spacer (silicon nitride surface), thereby causing the leakage current and influencing the performance of the semiconductor structure.

One key feature of the present invention is that in the present invention, for avoiding the defects occur between the silicon surface and the silicon nitride surface (such as the peeling off mentioned above), during the wet etching process P3, the spacer 218 will also be partially removed, so as to form the spacers 218′ with the rounding corners 219. In this case, the sharp corners mentioned above will not be formed, therefore, the epitaxial layer 240 can be formed on a smooth and concave surface conformally but not touching a sharp corner, thereby improving the quality of the epitaxial layer.

Besides, in the present invention, the recess 234 has an implanted bottom surface b2, and the implanted bottom surface b2 disposed under the epitaxial layer 240 (used as the source/drain regions of the transistor), in one aspect of the present invention, the implanted bottom surface b2 can also avoid the punch through phenomenon of the semiconductor structure. More precisely, for example, if the semiconductor structure is an NMOS transistor, and the implanted ions of the implanted bottom surface b2 includes p-type ions (such as boron or germanium ions), therefore, the electrons is not easy to punch through from the source region to the drain region while the supply voltage is high, thereby improving the product reliability. In another case, the semiconductor structure can also comprises a PMOS transistor, and the implanted ions of the implanted bottom surface b2 includes n-type ions, it should also be within the scope of the present invention.

In addition, compared with the semiconductor structure shown in FIG. 1, the epitaxial recess of the present invention can be formed through performing the steps P1-P3 in sequence. It is noteworthy that the diamond-shaped recess has at least a tip directing toward the channel region, therefore the epitaxial layer formed along the surface of the recess obtains a tip toward the channel region. Accordingly, effective stress provided by the epitaxial layer to the channel region is enhanced. On the other hand, the epitaxial layer formed along the flat bottom of the recess obtains a flat bottom consequently. Therefore, device leakage that used to occur at the tip is avoided. Briefly speaking, the manufacturing method provided by the present invention not only enhances the device performance but also the device reliability.

Those skilled in the art will readily observe that numerous modifications and alterations of the device and method may be made while retaining the teachings of the invention. Accordingly, the above disclosure should be construed as limited only by the metes and bounds of the appended claims.

1. A method for forming a semiconductor structure, comprising:
providing a substrate;
forming at least two gate structures on the substrate, each gate structure including two spacers disposed on two sides of the gate structure;
performing a dry etching process, to remove parts of the substrate, so as to form a recess in the substrate; and
performing a wet etching process, to etch partial sidewalls of the recess, so as to form at least two tips on two sides of the recess respectively, in addition, parts of the spacer are also removed through the wet etching process, and each spacer comprises a rounding corner disposed on a bottom surface of the spacer.

2. The method of claim 1, further comprising performing an ion implantation process on a bottom surface of the recess after the dry etching process is performed.

3. The method of claim 2, wherein the wet etching process is performed after the ion implantation process is performed.

4. The method of claim 2, wherein the ions used in the ion implantation process comprise boron ions, phosphate ions, arsenic ions, germanium ions, argon ions or a combination thereof.

5. The method of claim 1, wherein the recess is disposed in the substrate and between the two gate structures.

6. The method of claim 1, after the wet etching process is performed, further comprising forming an epitaxial layer in the recess.

7. The method of claim 6, wherein the epitaxial layer comprises silicon germanium (SiGe) or boron-doped silicon germanium (SiGeB) or silicon phosphide (SiP) or phosphorous-doped silicon carbide (SiCP).

8. The method of claim 1, wherein an angle between a tangent line of the rounding corner and a horizontal line is between 90 and 180 degrees.

9. The method of claim 1, wherein an angle between a tangent line of the rounding corner and a vertical line is between 90 and 180 degrees.

10. The method of claim 1, wherein the dry etching process is an isotropic etching process.

11. The method of claim 10, wherein the gas used in the first etching process comprises chlorine (Cl) mixed with helium (He).

12. The method of claim 1, wherein wet etching process uses a tetra methyl ammonium hydroxide ((CH₃)₄NOH, TMAH) solution.

13. A semiconductor structure, comprising:
a substrate, at least two gate structures disposed on the substrate;
at least two spacers disposed on two sides of each gate structure, wherein each spacer comprises a rounding corner on a bottom surface of the spacer; and
a recess disposed in the substrate between two gate structures, wherein the recess has a polygonal shaped cross section profile, and has at least two tips on two sides of the recess; and
an epitaxial layer filled in the recess.

14. The semiconductor structure of claim 13, wherein the polygonal shaped cross section profile is a hexagonal cross section profile.

15. The semiconductor structure of claim 13, wherein the two tips are disposed on a same level.

16. (canceled)

17. The semiconductor structure of claim 13, wherein the epitaxial layer comprises silicon germanium (SiGe) or boron-doped silicon germanium (SiGeB) or silicon phosphide (SiP) or phosphorous-doped silicon carbide (SiCP).

18. The semiconductor structure of claim 13, wherein a top surface of the epitaxial layer is higher than the rounding corner of each spacer.

19. The semiconductor structure of claim 13, wherein an angle between a tangent line of the rounding corner and a horizontal line is between 90 and 180 degrees.

20. The semiconductor structure of claim 13, wherein an angle between a tangent line of the rounding corner and a vertical line is between 90 and 180 degrees.
